(19) United States
(12) Patent Application Publication
(10) Pub. No.: US 2025/0261387 A1
(43) Pub. Date: Aug. 14, 2025

(54) SEMICONDUCTOR STRUCTURE AND METHOD OF MANUFACTURE

(71) Applicant: Taiwan Semiconductor Manufacturing Company Limited, Hsin-Chu (TW)

(72) Inventors: Kuo-Yu CHENG, Tainan City (TW); Chuan-feng CHEN, Hsinchu City (TW); Chi-Yuan WEN, Tainan City (TW); Kun-Yu LIN, Tainan County (TW); Chu Wen LIN, Hsin-Chu (TW)

(21) Appl. No.: 18/438,149

(22) Filed: Feb. 9, 2024

(51) Int. Cl. H01L 29/737; H01L 29/66

(52) U.S. Cl. CPC H10D 10/821; H10D 10/021

(57) ABSTRACT

In some embodiments, a method for forming a semiconductor structure includes forming an isolation structure in a collector semiconductor layer, forming a base dielectric layer over the collector semiconductor layer, and forming a first recess in the base dielectric layer. A base contact layer is formed over the base dielectric layer and in the first recess. A dielectric layer is formed over the base contact layer. A second recess is formed in the dielectric layer and the base contact layer to expose the collector semiconductor layer. Portions of the base contact layer are removed to form undercut regions under the base contact layer and over the collector semiconductor layer. A base semiconductor layer is formed in the second recess and the undercut regions. The base semiconductor layer contacts the base contact layer and the collector semiconductor layer. An emitter semiconductor layer is formed in the second recess and over the base semiconductor layer.

### BACKGROUND

Semiconductor devices are useful in a multitude of electronic devices, such as mobile phones, laptops, desktops, tablets, watches, gaming systems, and various other industrial, commercial, and consumer electronics. Semiconductor devices may be formed on a semiconductor substrate and may interact with components and/or layers of the semiconductor substrate to form various integrated circuit devices, such as high-power field-effect transistors, high-frequency transistors, heterojunction bipolar transistors (HBTs), etc. An HBT is a transistor incorporating a junction between two materials with different band gaps (i.e., a heterojunction) for the base, collector, and emitter instead of doped regions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-15 are illustrations of a semiconductor structure at various stages of fabrication, in accordance with some embodiments.

### DETAILED DESCRIPTION

The following disclosure provides many different embodiments, or examples, for implementing different features of the provided subject matter. Specific examples of components and structures are described below to simplify the present disclosure. These are, of course, merely examples and are not intended limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present application relates to a semiconductor structure and a method for fabricating a semiconductor structure. In accordance with some embodiments, a device, such as a heterojunction bipolar transistor (HBT) is formed with regions of a base contact layer contacting sidewall and upper surfaces of a base semiconductor layer to increase the contact area between the base semiconductor layer and the base contact layer. The base contact layer is formed in a first recess of a base dielectric layer. A second recess in the base contact layer exposes an underlying collector semiconductor layer. Portions of the base contact layer are removed to form undercut regions under the base contact layer and over the collector semiconductor layer. The base semiconductor layer is formed in the second recess and the undercut regions to contact the base contact layer and the collector semiconductor layer. A first heterojunction of the heterojunction bipolar transistor is defined between the base semiconductor layer and the collector semiconductor layer. An emitter semiconductor layer is formed over the base semiconductor layer. A second heterojunction of the heterojunction bipolar transistor is defined between the base semiconductor layer and the emitter semiconductor layer. The increased contact area between the base semiconductor layer and the base contact layer reduces the resistance of the connection between the base semiconductor layer and the base contact layer and increases the current gain of the heterojunction bipolar transistor. In some cases, voids may form during the formation of the undercut regions. The increased contact area between the base semiconductor layer and the base contact layer also mitigates the effects of any such voids.

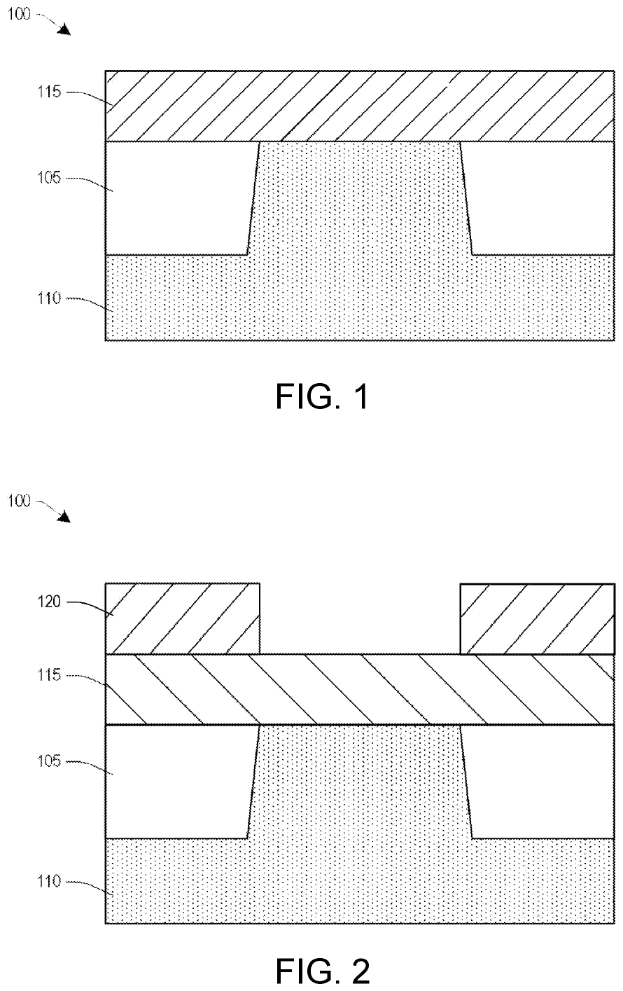

Referring to FIG. 1, a shallow trench isolation (STI) structure 105 is formed in a semiconductor layer 110, and a base dielectric layer 115 is formed over the semiconductor layer 110 and the STI structure 105, in accordance with some embodiments. In some embodiments, the semiconductor layer 110 is part of a substrate comprising at least one of an epitaxial layer, a single crystalline semiconductor material such as, but not limited to, at least one of Si, Ge, SiGe, InGaAs, GaAs, InSb, GaP, GaSb, InAlAs, GaSbP, GaAsSb, or InP, a silicon-on-insulator (SOI) structure, a wafer, or a die formed from a wafer. In some embodiments, the semiconductor layer 110 comprises at least one of crystalline silicon or other suitable materials. Other structures and/or configurations of the semiconductor layer 110 are within the scope of the present disclosure.

In some embodiments, the STI structure 105 is formed by forming at least one mask layer over the semiconductor layer 110. In some embodiments, the at least one mask layer comprises a layer of oxide material over the semiconductor layer 110 and a layer of nitride material over the layer of oxide material, and/or one or more other suitable layers. At least one of the at least one mask layer is removed to form an etch mask for use as a template to etch the semiconductor layer 110 to form a trench. A dielectric material is formed in the trench to form the STI structure 105. In some embodiments, the STI structure 105 includes multiple layers, such as an oxide liner, a nitride liner formed over the oxide liner, an oxide fill material formed over the nitride liner, and/or other suitable materials. In some embodiments, the STI structure 105 comprises multiple portions. The number of portions may vary. In some embodiments, the STI structure 105 comprises a single portion creating a contiguous structure in the Y-direction.

In some embodiments, a fill material of the STI structure 105 is formed using a high density (HDP) plasma process. The HDP process uses precursor gases comprising at least one of silane (SiH₄), oxygen, argon, or other suitable gases. The HDP process includes a deposition component, which forms material on surfaces defining the trench, and a sputtering component, which removes or relocates deposited material. A deposition-to-sputtering ratio depends on gas ratios employed during the deposition. In accordance with some embodiments, argon and oxygen act as sputtering sources, and the particular values of the gas ratios are determined based on an aspect ratio of the trench. After forming the fill material, an anneal process is performed to densify the fill material. In some embodiments, the STI structure 105 generates compressive stress that serves to compress a portion of the semiconductor layer 110. Other structures and/or configurations of the STI structure 105 are within the scope of the present disclosure.

Although the semiconductor layer 110 and the STI structure 105 are illustrated as having coplanar upper surfaces at an interface where the semiconductor layer 110 abuts the STI structure 105, the relative heights can vary. For example, the STI structure 105 can be recessed relative to the semiconductor layer 110, or the semiconductor layer 110 can be recessed relative to the STI structure 105. The relative heights at the interface depend on the processes performed for forming the STI structure 105, such as at least one of deposition, planarization, mask removal, surface treatment, or other suitable techniques.

The base dielectric layer 115 comprises silicon dioxide, a low-k dielectric material, one or more layers of low-k dielectric material, and/or other suitable materials. Low-k dielectric materials have a k value lower than about 3.9. The materials for the base dielectric layer 115 may comprise at least one of Si, O, C, or H, such as carbon doped oxide dielectrics, SiCOH or SiOC, or other suitable materials. Organic material, such as polymers, may be used for the base dielectric layer 115. The base dielectric layer 115 may comprise at least one of a carbon-containing material, organo-silicate glass, a porogen-containing material, nitrogen, and/or other suitable materials. The base dielectric layer 115 may be formed by at least one of atomic layer deposition (ALD), physical vapor deposition (PVD), chemical vapor deposition (CVD), low pressure chemical vapor deposition (LPCVD), atomic level chemical vapor deposition (ALCVD), ultrahigh vacuum chemical vapor deposition (UHVCVD), remote plasma chemical vapor deposition (RPCVD), plasma enhanced chemical vapor deposition (PECVD), molecular beam epitaxy (MBE), liquid phase epitaxy (LPE), spin coating, spin-on technology, or other suitable techniques.

Referring to FIG. 2, a patterned mask layer 120 is formed over the base dielectric layer 115, in accordance with some embodiments. In accordance with some embodiments, the patterned mask layer 120 comprises a plurality of individually formed layers that together form a mask stack. In some embodiments, the patterned mask layer 120 comprises at least one of a hard mask layer, a bottom antireflective coating (BARC) layer, an organic planarization layer (OPL), or a photoresist layer. The hard mask layer is formed by at least one of ALD, PVD, CVD, LPCVD, ALCVD, UHVCVD, RPCVD, PECVD, MBE, LPE, spin coating, spin-on technology, or other suitable techniques. In some embodiments, the hard mask layer comprises at least one of silicon and oxygen, silicon and nitrogen, nitrogen, silicon (e.g., polycrystalline silicon), or other suitable materials. In some embodiments, the BARC layer is a polymer layer that is applied using a spin coating process. In some embodiments, the OPL comprises a photo-sensitive organic polymer that is applied using a spin coating process. In some embodiments, the OPL comprises a dielectric layer. In some embodiments, the photoresist layer is formed by at least one of spinning, spray coating, or other suitable techniques. The photoresist can be a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative image of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist. One or more etchants have a selectivity such that the one or more etchants remove or etch away one or more layers exposed or not covered by the photoresist at a greater rate than the one or more etchants remove or etch away the photoresist. Accordingly, an opening in the photoresist allows the one or more etchants to form a corresponding opening in the one or more layers under the photoresist, and thereby transfer a pattern in the photoresist to the one or more layers under the photoresist. The photoresist is stripped or washed away after the pattern transfer. The layers of the mask stack are patterned to form the patterned mask layer 120. In some embodiments, the photoresist layer is exposed using a radiation source and a reticle to define a pattern in the photoresist layer, and portions of the photoresist layer are removed to define a patterned photoresist layer. The underlying OPL, BARC layer, and hard mask layer are etched using the patterned photoresist layer as a template to form the patterned mask layer 120 and expose portions of the base dielectric layer 115 through the patterned mask layer 120. Other structures and configurations of the patterned mask layer 120 are within the scope of the present disclosure.

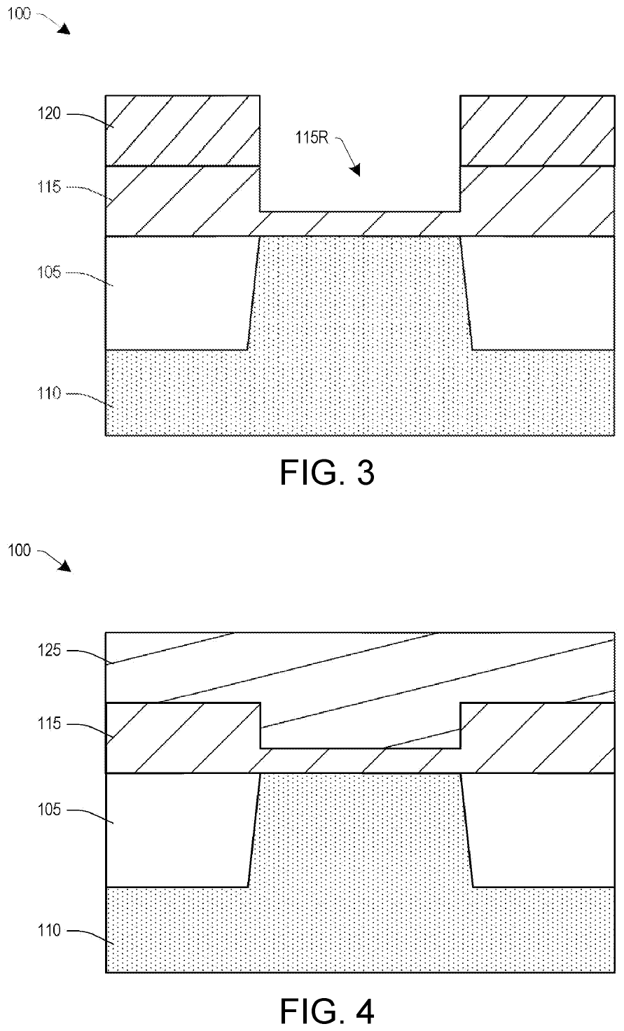

Referring to FIG. 3, a patterning process is performed to form a recess 115R in the base dielectric layer 115, in accordance with some embodiments. An etching process is performed using the patterned mask layer 120 as an etch template to pattern the base dielectric layer 115 to form the recess 115R. In some embodiments, the etching process is at least one of a plasma etching process, a reactive ion etching (RIE) process, or other suitable techniques. The etch process may be a timed etch process. In some embodiments, the depth of the recess 115R is greater than at least one fourth the thickness of the base dielectric layer 115.

Referring to FIG. 4, the patterned mask layer 120 is removed, and a base contact layer 125 is formed over the base dielectric layer 115 and in the recess 115R, in accordance with some embodiments. The base contact layer 125 may be a polysilicon layer. In some embodiments, the base contact layer 125 is doped polysilicon. The polysilicon may be doped with dopants, also referred to as impurities, to enhance the conductivity of the polysilicon. Suitable dopants include n-type impurities, such as at least one of phosphorous, arsenic, or other suitable n-type dopants or p-type impurities, such as at least one of boron, BF₂, or other suitable p-type dopants. The base contact layer 125 may be formed by at least one of ALD, PVD, CVD, LPCVD, ALCVD, UHVCVD, RPCVD, PECVD, MBE, LPE, spin coating, spin-on technology, or other suitable techniques. In some embodiments, a planarization process is performed to planarize an upper surface of the base contact layer 125.

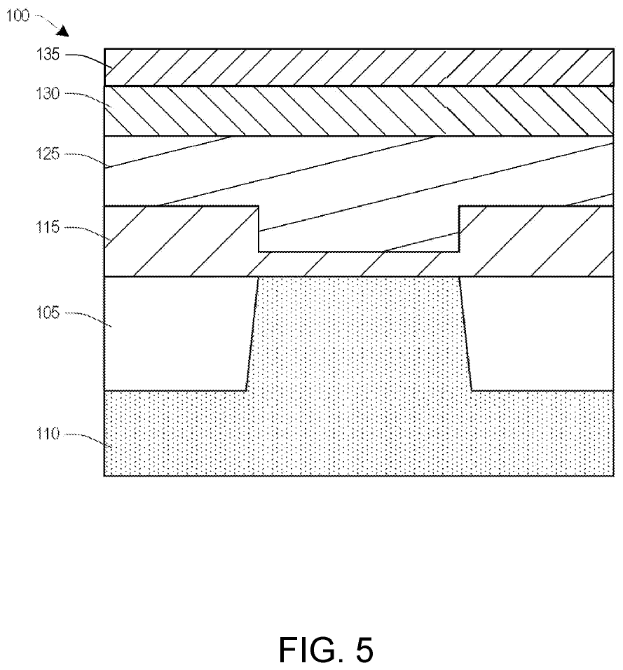

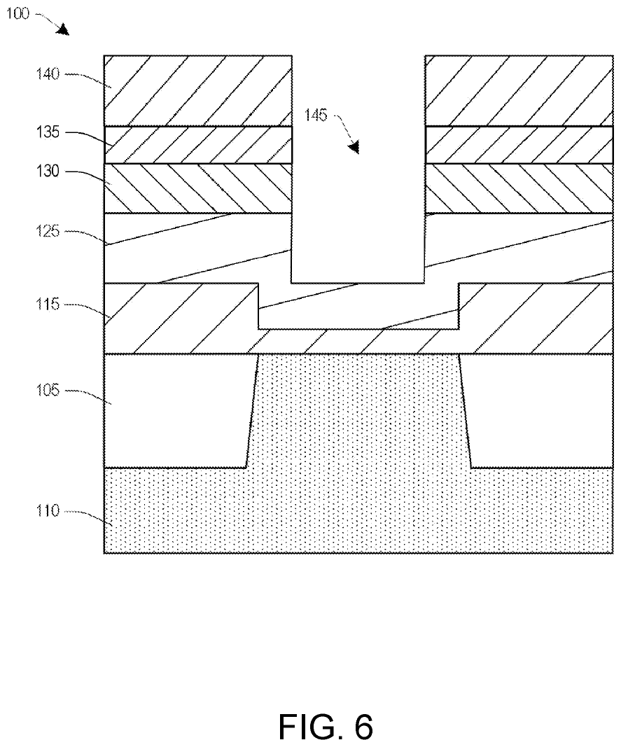

Referring to FIG. 5, dielectric layers 130, 135 are formed over the base contact layer 125, in accordance with some embodiments. The dielectric layer 130 comprises silicon dioxide, a low-k dielectric material, one or more layers of low-k dielectric material, and/or other suitable materials. The materials for the dielectric layer 130 may comprise at least one of Si, O, C, or H, such as carbon doped oxide dielectrics, SiCOH, or SiOC, or other suitable materials. Organic material such as polymers may be used for the dielectric layer 130. The dielectric layer 130 may comprise at least one of a carbon-containing material, organo-silicate glass, a porogen-containing material, nitrogen, and/or or other suitable materials. The dielectric layer 130 may be formed by at least one of ALD, PVD, CVD, LPCVD, ALCVD, UHVCVD, RPCVD, PECVD, MBE, LPE, spin coating, spin-on technology, or other suitable techniques. In some embodiments, the dielectric layer 135 comprises a material with etch selectivity with respect to a material of the dielectric layer 130. For example, where the dielectric layer 130 is an oxide based material, the dielectric layer 135 may be a nitride based material, such as silicon nitride, to provide etch selectivity with respect to the oxide based material. The dielectric layer 135 may be formed by at least one of ALD, PVD, CVD, LPCVD, ALCVD, UHVCVD, RPCVD, PECVD, MBE, LPE, spin coating, spin-on technology, or other suitable techniques.

Referring to FIG. 6, a patterned mask layer 140 is formed over the dielectric layer 135, and a patterning process is performed to form a recess 145 that extends through the dielectric layers 130, 135 and a least partially through the base contact layer 125, in accordance with some embodiments. The patterned mask layer 140 is formed using at least one of a hard mask layer, a BARC layer, an OPL, or a photoresist layer comprising materials and formed as described herein. An etching process is performed using the patterned mask layer 140 as an etch template to pattern the dielectric layer 135, the dielectric layer 130, and the base contact layer 125 to form the recess 145. The etching process may employ multiple etching processes with different etch chemistries to form the recess 145. For example, a first etching process may etch through the dielectric layer 135 and may terminate based on detecting the exposure of the dielectric layer 130. A second etching process may etch through the dielectric layer 130 and may terminate based on detecting the exposure of the base contact layer 125. A third etching process, such as a timed etching process, may be used to extend the recess 145 at least partially through the base contact layer 125, such as through the portion of the base contact layer 125 that does not extend into the base dielectric layer 115. In some embodiments, the etching processes include at least one of a plasma etching process, an RIE process, or other suitable techniques.

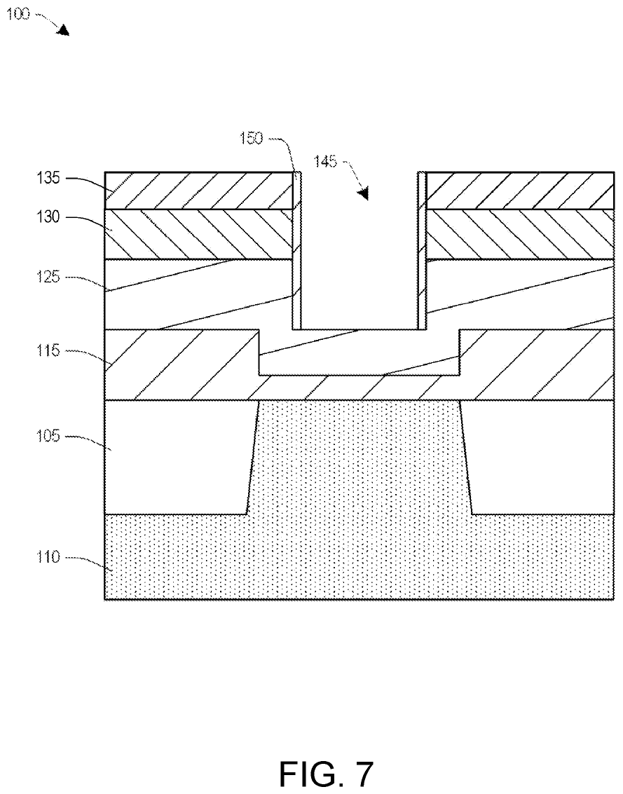

Referring to FIG. 7, the patterned mask layer 140 is removed and a sidewall spacer 150 is formed in the recess 145, in accordance with some embodiments. In some embodiments, the sidewall spacer 150 is formed by depositing a conformal spacer layer over the dielectric layer 135 and in the recess 145 and performing an anisotropic etch process to remove portions of the spacer layer positioned on horizontal surfaces of the dielectric layer 135 and the base contact layer 125. The conformal spacer layer may be formed by at least one of ALD, PVD, CVD, LPCVD, ALCVD, UHVCVD, RPCVD, PECVD, MBE, or other suitable techniques. In some embodiments, the sidewall spacer 150 comprises nitrogen, silicon, and/or other suitable materials. Other structures and/or configurations of the sidewall spacer 150 are within the scope of the present disclosure.

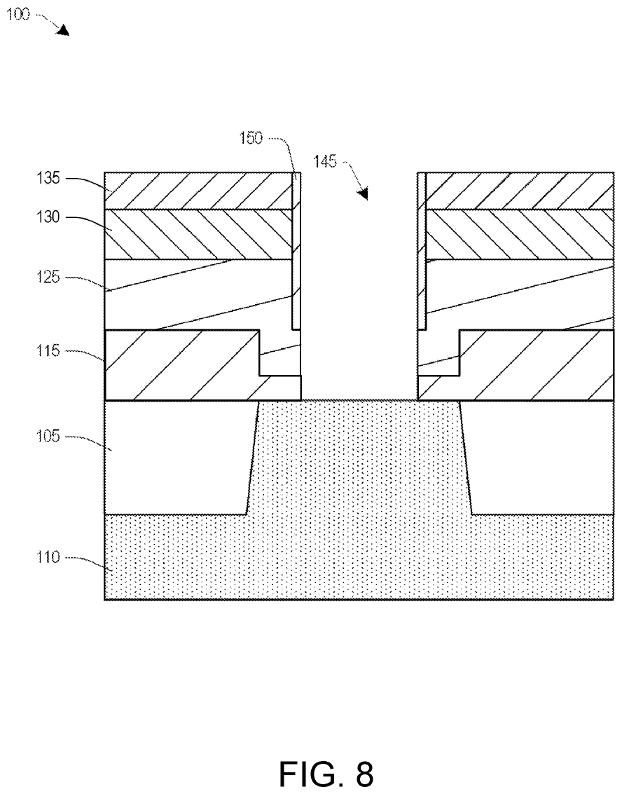

Referring to FIG. 8, portions of the base contact layer 125 and the base dielectric layer 115 are removed to expose the semiconductor layer 110, in accordance with some embodiments. An etching process may be performed to remove the portions of the base contact layer 125 and the base dielectric layer 115. The etching process may employ multiple etching processes with different etch chemistries to extend the recess 145. For example, a first etching process may etch through the base contact layer 125 and may terminate based on detecting the exposure of the base dielectric layer 115. A second etching process may etch through the base dielectric layer 115 and may terminate based on detecting the exposure of the semiconductor layer 110. In some embodiments, the etching processes include at least one of a plasma etching process, an RIE process, or other suitable techniques.

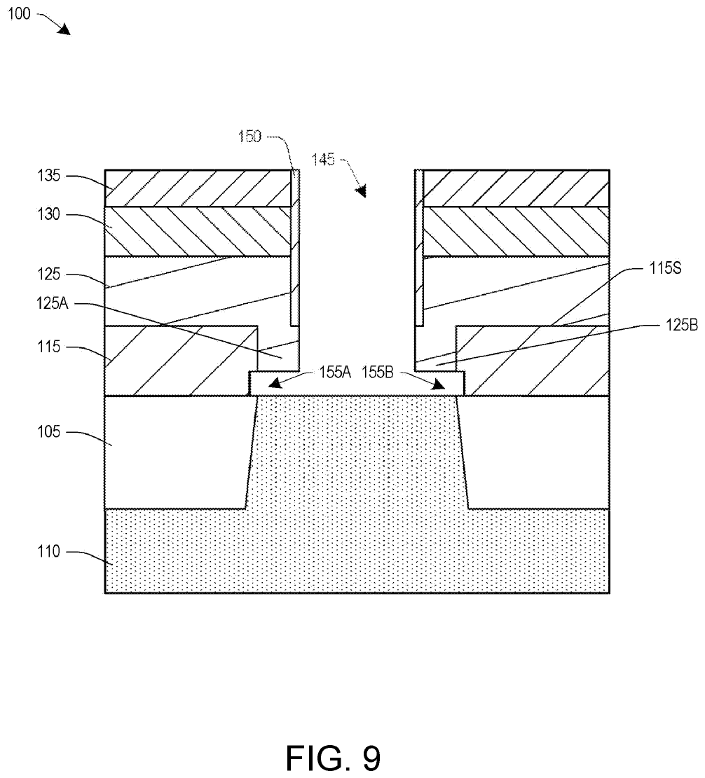

Referring to FIG. 9, portions of the base dielectric layer 115 are removed to form undercut regions 155A, 155B under the base contact layer 125, in accordance with some embodiments. An etching process, such as a wet etch, may be performed to remove portions of the base dielectric layer 115 selectively to the dielectric layer 135, the base contact layer 125, and the sidewall spacer 150 to form the undercut regions 155A, 155B. In some embodiments, the undercut regions extend laterally greater than a width of ladder portions 125A, 125B of the base contact layer 125 extending below an upper surface 115S of the base dielectric layer 115.

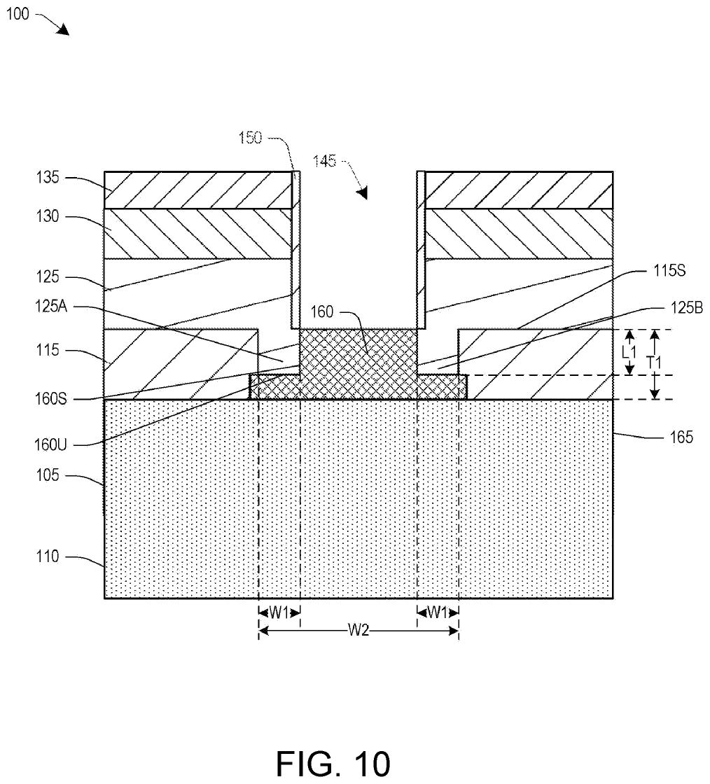

Referring to FIG. 10, a base semiconductor layer 160 is formed in the recess 145 and the undercut regions 155A, 155B, in accordance with some embodiments. The base semiconductor layer 160 may be silicon-germanium (SiₓGe(iₓ) where x ranges from 0.25 to 0.85). In some embodiments, a selective epitaxial growth process is performed to form the base semiconductor layer 160. Due to a lattice mismatch between the semiconductor layer 110 and the base semiconductor layer 160, a first heterojunction 165 is defined at the interface between the semiconductor layer 110 and the base semiconductor layer 160. In some embodiments, a width, W1, of each of the ladder portions 125A, 125B of the base contact layer 125 extending below the upper surface 115S of the base dielectric layer 115 is between about one fourth and one half a width, W2, of the base semiconductor layer 160 resulting in the base contact layer 125 contacting an upper surface 160U of the base semiconductor layer 160 an amount corresponding to the width relationship. This width relationship with respect to the interface on the upper surface 115S increases the contact area between the base contact layer 125 and the base semiconductor layer 160 to reduce the resistance of the connection therebetween. The ladder portions 125A, 125B of the base contact layer 125 also contact a sidewall surface 160S of the base semiconductor layer 160. The length, L1, of the sidewall surface 160S extends at least one fourth the thickness, T1, of the base semiconductor layer 160. This length to thickness relationship also increases the contact area between the base contact layer 125 and the base semiconductor layer 160 to reduce the resistance of the connection therebetween.

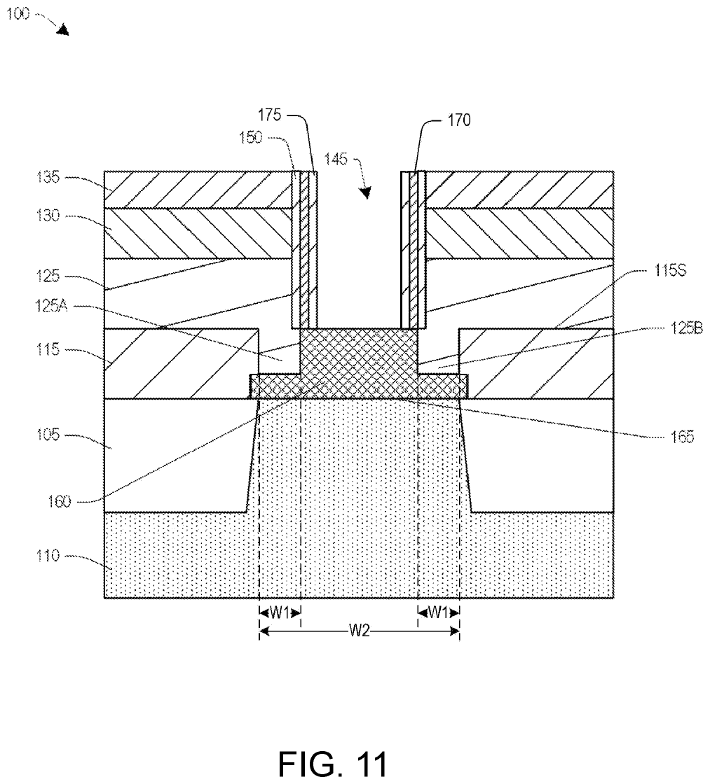

Referring to FIG. 11, sidewall spacers 170, 175 are formed in the recess 145, in accordance with some embodiments. In some embodiments, the sidewall spacers 170, 175 are each formed by depositing a conformal spacer layer over the dielectric layer 135 and in the recess 145 and performing an anisotropic etch process to remove portions of the spacer layer positioned on horizontal surfaces of the dielectric layer 135 and the base semiconductor layer 160. The conformal spacer layers may be formed by at least one of ALD, PVD, CVD, LPCVD, ALCVD, UHVCVD, RPCVD, PECVD, MBE, or other suitable techniques. In some embodiments, the sidewall spacer 170 comprises silicon and oxygen, and/or other suitable materials, and the sidewall spacer 175 comprises silicon and nitrogen, and/or other suitable materials. The material of the sidewall spacer 175 may be the same as the material of the sidewall spacer 150. Other structures and/or configurations of the sidewall spacers 170, 175 are within the scope of the present disclosure.

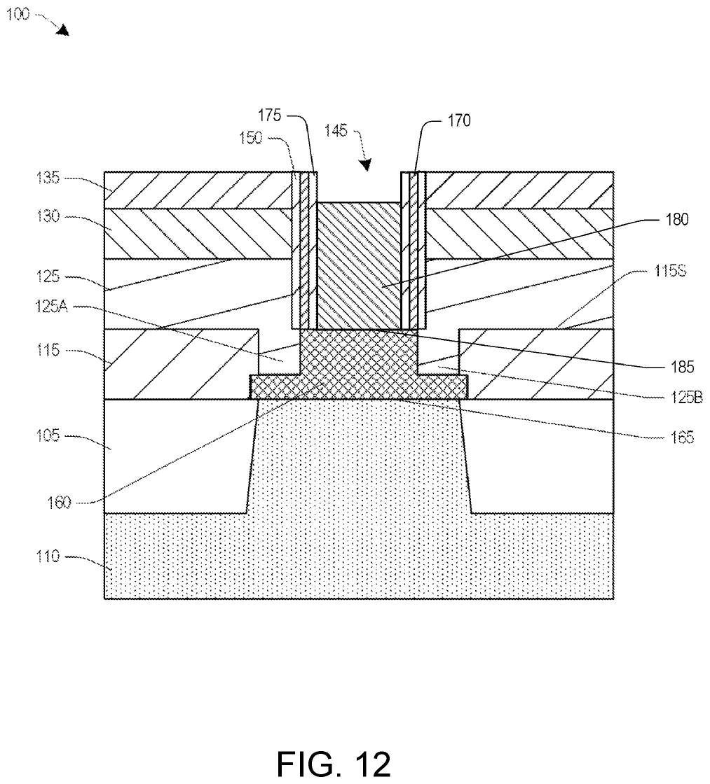

Referring to FIG. 12, an emitter semiconductor layer 180 is formed in the recess 145 over the base semiconductor layer 160, in accordance with some embodiments. The emitter semiconductor layer 180 may be silicon. In some embodiments, a selective epitaxial growth process is performed to form the emitter semiconductor layer 180. Due to a lattice mismatch between the base semiconductor layer 160 and the emitter semiconductor layer 180, a second heterojunction 185 is defined at the interface between the base semiconductor layer 160 and the emitter semiconductor layer 180. The sidewall spacers 150, 170, 175 isolate the emitter semiconductor layer 180 from the base contact layer 125.

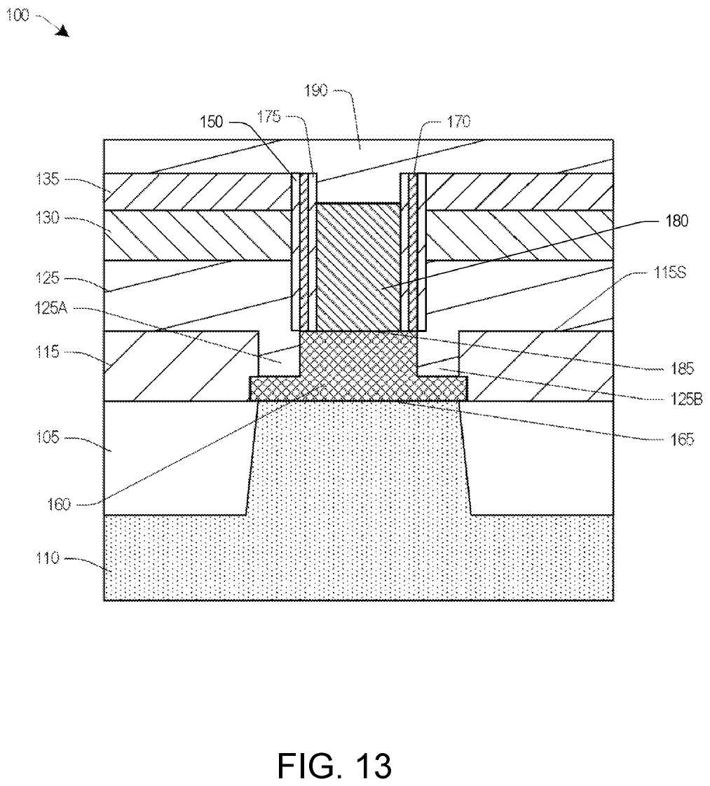

Referring to FIG. 13, an emitter contact layer 190 is formed over the emitter semiconductor layer 180, in accordance with some embodiments. The emitter contact layer 190 may be a polysilicon layer. In some embodiments, the emitter contact layer 190 is doped polysilicon. The polysilicon may be doped with dopants, also referred to as impurities, to enhance the conductivity of the polysilicon. Suitable dopants include n-type impurities, such as at least one of phosphorous, arsenic, or other suitable n-type dopants or p-type impurities, such as at least one of boron, BF₂, or other suitable p-type dopants. The emitter contact layer 190 may be formed by at least one of ALD, PVD, CVD, LPCVD, ALCVD, UHVCVD, RPCVD, PECVD, MBE, LPE, spin coating, spin-on technology, or other suitable techniques. In some embodiments, a planarization process is performed to planarize an upper surface of the emitter contact layer 190. The emitter contact layer 190 may be the same material as the base contact layer 125.

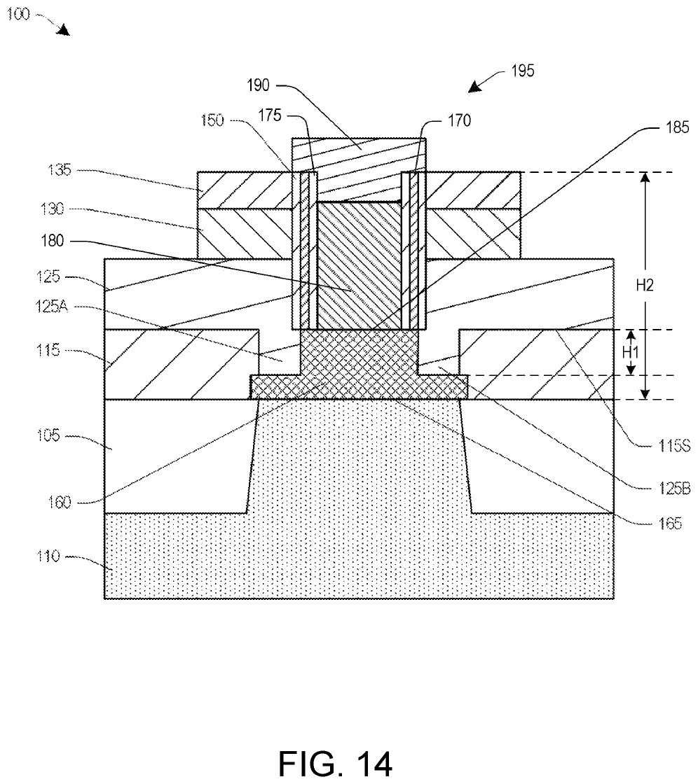

Referring to FIG. 14, portions of the emitter contact layer 190, the dielectric layer 135, and the dielectric layer 130 are removed, in accordance with some embodiments. The portions of the emitter contact layer 190, the dielectric layer 135, and the dielectric layer 130 may be removed using etching processes in the presence of patterned mask layers. The patterned mask layers may be formed using at least one of a hard mask layer, a BARC layer, an OPL, or a photoresist layer comprising materials and formed as described herein.

In some embodiments, a first patterning process with a first patterned mask layer removes portions of the emitter contact layer 190, the dielectric layer 135, and the dielectric layer 130 to expose the base contact layer 125. The first patterning process may include multiple etching processes with different etch chemistries to remove the portions of the emitter contact layer 190, the dielectric layer 135, and the dielectric layer 130. For example, a first etching process may etch through the emitter contact layer 190 and may terminate based on detecting the exposure of the dielectric layer 135. A second etching process may etch through the dielectric layer 135 and may terminate based on detecting the exposure of the dielectric layer 130. A third etching process may etch through the dielectric layer 130 and may terminate based on detecting the exposure of the base contact layer 125. In some embodiments, the etching processes include at least one of a plasma etching process, an RIE process, or other suitable techniques.

In some embodiments, a second patterning process with a second patterned mask layer removes other portions of the emitter contact layer 190. The second patterning process may include an etching process with an etch chemistry to remove the portions of the emitter contact layer 190 selective to the materials of the dielectric layer 135. The etching process may etch through the emitter contact layer 190 and may terminate based on detecting the exposure of the dielectric layer 135. In some embodiments, the etching process includes at least one of a plasma etching process, an RIE process, or other suitable techniques.

The semiconductor layer 110, the base semiconductor layer 160, and the emitter semiconductor layer 180 define a heterojunction bipolar transistor 195 with heterojunctions 165, 185. The semiconductor layer 110 defines a collector semiconductor layer of the heterojunction bipolar transistor 195. In some embodiments, the height, H1, of the ladder portions 125A, 125B of base contact layer 125 extending below an upper surface 115S of the base dielectric layer 115 is less than about one third the height, H2, of the heterojunction bipolar transistor 195 above the semiconductor layer 110. The ladder portions 125A, 125B of base contact layer 125 extending below an upper surface 115S of the base dielectric layer 115 increase the contact area between the base contact layer 125 and the base semiconductor layer 160, thereby decreasing the base resistance and reducing the effects of any voids that may form during processing, such as at the interface between the base semiconductor layer 160 and the sidewall spacer 150 or at the interface between the base contact layer 125 and the sidewall spacer 150. During the processing illustrated in FIG. 8, portions of the sidewall spacer 150 or the base contact layer 125 near the bottom of the sidewall spacer 150 can be eroded, such that a void may be created when the base semiconductor layer 160 is subsequently formed in the recess 145. Reducing the base resistance increases the current gain of the heterojunction bipolar transistor 195.

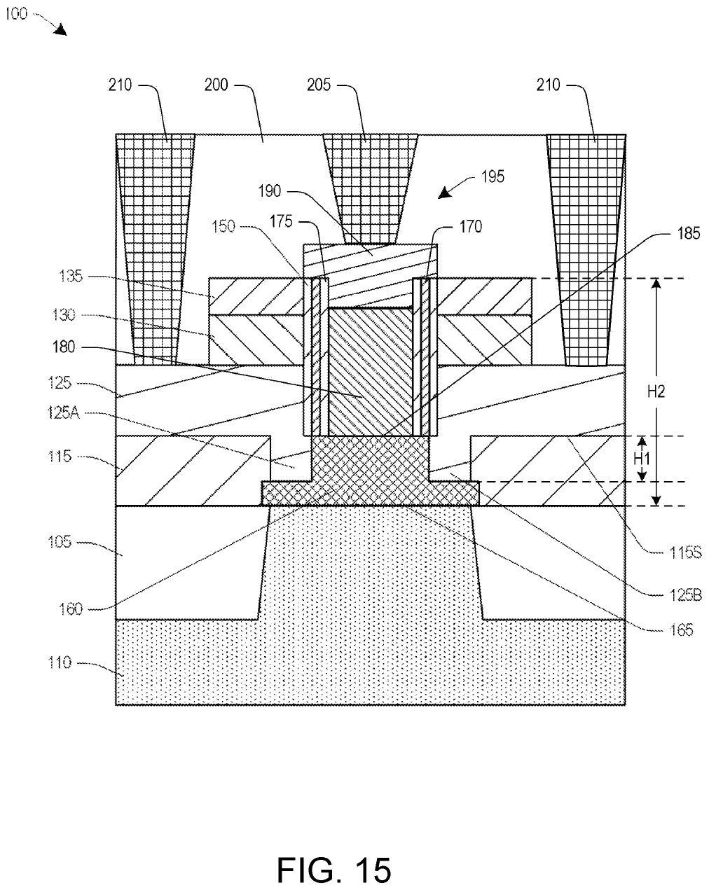

Referring to FIG. 15, a dielectric layer 200 is formed over the base contact layer 125, the dielectric layer 135, and the emitter contact layer 190 of the heterojunction bipolar transistor 195, and contacts 205, 210 are formed in the dielectric layer 200, in accordance with some embodiments. The contact 205 contacts the emitter contact layer 190, and the contacts 210 contact the base contact layer 125. One or more additional contacts may be formed to contact the semiconductor layer 110 serving as the collector of the heterojunction bipolar transistor 195. Such contacts may be located in a different region of the heterojunction bipolar transistor 195 such as into or out of the page, or laterally to the left or right of the heterojunction bipolar transistor 195 in the illustrated view. The dielectric layer 200 may comprise a material with a medium or low dielectric constant, such as silicon dioxide. The dielectric layer 200 may be formed in any number of ways, such as by thermal growth, chemical growth, ALD, CVD, PECVD, and/or other suitable techniques. In some embodiments, via openings are formed in the dielectric layer 200 to expose the emitter contact layer 190 and the base contact layer 125, and the via openings are filled with a conductive material and planarized to form the contacts 205, 210. A subsequent dielectric layer with trenches formed therein may be employed to form conductive lines contacting the contacts 205, 210 as part of a metallization structure, for example using a dual damascene process. In some embodiments, the contacts 205, 210 comprise a barrier layer, a seed layer, a metal fill layer, and/or other suitable layers. In some embodiments, the metal fill layer comprises W, Ru, Ir, a metal silicide, and/or other suitable materials. Other structures and/or configurations of the contacts 205, 210 are within the scope of the present disclosure. Additional metallization layers may be formed in the semiconductor structure. The heterojunction bipolar transistor 195 may be a discrete device or it may be formed in conjunction with other semiconductor devices, such as field effect transistors, logic devices, memory devices, or other devices in different regions of a semiconductor die. These different regions may be in the same of different voltage domains depending on the operating voltages of the respective devices.

A method for forming a semiconductor structure includes forming an isolation structure in a collector semiconductor layer, forming a base dielectric layer over the collector semiconductor layer, and forming a first recess in the base dielectric layer. A base contact layer is formed over the base dielectric layer and in the first recess. A dielectric layer is formed over the base contact layer. A second recess is formed in the dielectric layer and the base contact layer to expose the collector semiconductor layer. Portions of the base contact layer are removed to form undercut regions under the base contact layer and over the collector semiconductor layer. A base semiconductor layer is formed in the second recess and the undercut regions. The base semiconductor layer contacts the base contact layer and the collector semiconductor layer. An emitter semiconductor layer is formed in the second recess and over the base semiconductor layer.

A semiconductor structure includes a collector semiconductor layer, a base semiconductor layer contacting the collector semiconductor layer, a base contact layer contacting the base semiconductor layer, an emitter semiconductor layer contacting the base semiconductor layer, and an emitter contact layer contacting the emitter semiconductor layer. The base contact layer includes a ladder portion extending laterally over an upper surface of the base semiconductor layer and the ladder portion of the base contact layer has a width of at least one fourth a width of the base semiconductor layer.

A semiconductor structure includes a collector semiconductor layer, a base semiconductor layer contacting the collector semiconductor layer, a base dielectric layer adjacent the base semiconductor layer, a base contact layer contacting the base semiconductor layer, an emitter semiconductor layer contacting the base semiconductor layer, and an emitter contact layer contacting the emitter semiconductor layer. The base contact layer comprises a ladder portion extending below an upper surface of the base dielectric layer to contact a portion of a sidewall surface of the base semiconductor layer and the sidewall surface has a height of at least one fourth a thickness of the base semiconductor layer.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is not limited thereto. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one or more of several implementations, such feature may be combined with one or more other features of the other implementations as may be desired and advantageous for any given or particular application.

What is claimed is:

1. A method for forming a semiconductor structure, comprising:
forming an isolation structure in a collector semiconductor layer;
forming a base dielectric layer over the collector semiconductor layer;
forming a first recess in the base dielectric layer;
forming a base contact layer over the base dielectric layer and in the first recess;
forming a dielectric layer over the base contact layer;
forming a second recess in the dielectric layer and the base contact layer to expose the collector semiconductor layer;
removing portions of the base contact layer to form undercut regions under the base contact layer and over the collector semiconductor layer;
forming a base semiconductor layer in the second recess and the undercut regions, the base semiconductor layer contacting the base contact layer and the collector semiconductor layer; and
forming an emitter semiconductor layer in the second recess and over the base semiconductor layer.

2. The method of claim 1, comprising:
forming an emitter contact layer in the second recess and over the emitter semiconductor layer.

3. The method of claim 2, wherein forming the emitter contact layer comprises forming the emitter contact layer over the dielectric layer.

4. The method of claim 1, wherein forming the second recess comprises:
performing a first process to remove a portion of the dielectric layer and a first portion of the base contact layer less than a thickness of the base contact layer;
forming a sidewall spacer in the second recess; and
performing a second process to remove a second portion of the base contact layer to expose the collector semiconductor layer.

5. The method of claim 4, wherein removing the portions of the base contact layer to form the undercut regions comprises:
performing an etch process to undercut the sidewall spacer and removing the portions of the base contact layer lower than the sidewall spacer.

6. The method of claim 4, comprising:
forming a second sidewall spacer adjacent the sidewall spacer after forming the base semiconductor layer and prior to forming the emitter semiconductor layer.

7. The method of claim 1, wherein:
forming the base semiconductor layer in the second recess comprises forming the base semiconductor layer in the undercut regions under ladder portions of the base contact layer, and
a width of one of the ladder portions is at least one fourth a width of the base semiconductor layer.

8. The method of claim 1, wherein:
forming the base semiconductor layer in the second recess comprises forming the base semiconductor layer in the undercut regions under ladder portions of the base contact layer,
a sidewall of one of the ladder portions contacts a sidewall of the base semiconductor layer, and
a length of the sidewall of the base semiconductor layer is at least one fourth a thickness of the base semiconductor layer.

9. The method of claim 1, wherein:
forming the base semiconductor layer comprises forming the base semiconductor layer comprising a first material, and
forming the emitter semiconductor layer comprises forming the emitter semiconductor layer comprising second material having a lattice mismatch with respect to the first material to define a first heterojunction at an interface between the base semiconductor layer and the emitter semiconductor layer.

10. The method of claim 9, wherein:
forming the collector semiconductor layer comprises forming the collector semiconductor layer comprising a third material having a lattice mismatch with respect to the first material to define a second heterojunction at an interface between the collector semiconductor layer and the base semiconductor layer.

11. A semiconductor structure, comprising:
a collector semiconductor layer;
a base semiconductor layer contacting the collector semiconductor layer;
a base contact layer contacting the base semiconductor layer;
an emitter semiconductor layer contacting the base semiconductor layer; and
an emitter contact layer contacting the emitter semiconductor layer, wherein:
the base contact layer comprises a ladder portion extending laterally over an upper surface of the base semiconductor layer, and
the ladder portion of the base contact layer has a width of at least one fourth a width of the base semiconductor layer.

12. The semiconductor structure of claim 11, wherein:
the base semiconductor layer comprises a first material, and
the emitter semiconductor layer comprises a second material having a lattice mismatch with respect to the first material to define a first heterojunction at an interface between the base semiconductor layer and emitter semiconductor layer.

13. The semiconductor structure of claim 12, wherein:
the second material comprises silicon and the first material comprises silicon germanium.

14. The semiconductor structure of claim 12, wherein:
the collector semiconductor layer comprises a third material having a lattice mismatch with respect to the first material to define a second heterojunction at an interface between the collector semiconductor layer and the base semiconductor layer.

15. The semiconductor structure of claim 14, wherein:
the first material comprises silicon germanium and the third material comprises silicon.

16. A semiconductor structure, comprising:
a collector semiconductor layer;
a base semiconductor layer contacting the collector semiconductor layer;
a base dielectric layer adjacent the base semiconductor layer;
a base contact layer contacting the base semiconductor layer;
an emitter semiconductor layer contacting the base semiconductor layer; and
an emitter contact layer contacting the emitter semiconductor layer, wherein:
the base contact layer comprises a ladder portion extending below an upper surface of the base dielectric layer to contact a portion of a sidewall surface of the base semiconductor layer, and
the sidewall surface has a length of at least one fourth a thickness of the base semiconductor layer.

17. The semiconductor structure of claim 16, wherein:
the base semiconductor layer comprises a first material, and
the emitter semiconductor layer comprises a second material having a lattice mismatch with respect to the first material to define a first heterojunction at an interface between the base semiconductor layer and the emitter semiconductor layer.

18. The semiconductor structure of claim 17, wherein:
the second material comprises silicon and the first material comprises silicon germanium.

19. The semiconductor structure of claim 17, wherein:
the collector semiconductor layer comprises a third material having a lattice mismatch with respect to the first material to define a second heterojunction at an interface between the collector semiconductor layer and the base semiconductor layer.

20. The semiconductor structure of claim 19, wherein:
the first material comprises silicon germanium and the third material comprises silicon.
